(19) United States
(12) Patent Application Publication
(10) Pub. No.: US 2026/0354209 A1
(43) Pub. Date: Nov. 5, 2026

(54) COMBINED DC/AC BOND PAD STRUCTURE FOR RF CIRCUIT INTEGRATION

(71) Applicant: AmpliTech Group, Inc., Hauppauge, NY (US)

(72) Inventors: James Mason Carroll, Allen, TX (US); Bumjin Kim, Frisco, TX (US)

(21) Appl. No.: 19/661,255

(22) Filed: Apr. 28, 2026

Related U.S. Application Data
(60) Provisional application No. 63/797,713, filed on Apr. 30, 2025.

(51) Int. Cl. H10W 44/20; G06F 30/392; H10W 72/59; H10W 90/00; H10W 90/10

(52) U.S. Cl. CPC H10W 44/243; G06F 30/392; H10W 44/206; H10W 44/226; H10W 72/59; H10W 90/10; H10W 90/753

(57) ABSTRACT

A semiconductor substrate includes a plurality of pads able to support both DC and AC signals with a single connection point to an RF integrated circuit. At least one blocking mechanism on the semiconductor substrate is connected to at least one of the plurality of pads and includes passive components that can prevent unwanted current flow to circuits located externally with respect to the semiconductor substrate. In some embodiments, at least one of a device and circuit are able to provide both direct current (DC) and radio frequency (RF) functionality and are connectable to the plurality of pads.

### RELATED APPLICATION

This application claims the priority benefit of U.S. Provisional Patent Application No. 63/797,713, titled “Combined DC/AC Bond Pad Structure for RF Circuit Integration” filed Apr. 30, 2025, the disclosure of which is incorporated by reference herein in its entirety.

### TECHNICAL FIELD

The present disclosure generally relates to compact layout designs for circuits on a semiconductor substrate that integrate devices and circuits capable of providing both Direct Current (DC) and Alternating Current (AC) connections to the same Radio Frequency (RF) pads. More particularly, a novel architecture supporting mechanisms that optionally block DC signals and include flexible interconnects is described to support dual-mode electrical coupling at those interconnection points.

### BACKGROUND

Radio frequency (RF) circuits are crucial in wireless communication systems, where they perform essential functions such as amplification, attenuation, filtering, phase shifting, time delay, and frequency translation. These functions are implemented through active and passive components like amplifiers, mixers, and multipliers. Modern semiconductor technologies, including those based on silicon (Si) CMOS (Complementary Metal-Oxide-Semiconductor) and III-V GaAs (Gallium Arsenide) allow these RF circuits to be integrated into miniature integrated circuit (IC) chips utilizing wafer-level processing.

In RF systems, various components and functions can be combined into RF paths, also known as RF line-ups or RF chains, to create higher-level system functionality. A common challenge in these RF chains is the need for DC blocking to prevent unwanted current flow or "sinking" current between ICs. Uncontrolled current flow can degrade circuit performance, cause damage, and compromise both short-term functionality and long-term reliability.

To mitigate this, designers often include DC blocking mechanisms within the chip layout, or system designers may employ external components, such as blocking capacitors, between RF functions. However, incorporating DC blocking within the chip can limit the low-frequency bandwidth of RF circuits, which is particularly problematic for broadband circuits intended for the general RF market. Without effective DC blocking, external voltages can lead to performance degradation or even damage to the IC or other components in the RF system chain.

What is needed are compact circuit layouts on a semiconductor substrate that integrate devices and circuits capable of providing both Direct Current (DC) and Alternating Current (AC) connections to the same Radio Frequency (RF) connection pads. Such compact layouts should enable dual functionality at a single connection point and offer greater flexibility in RF circuit design. Further, designs are needed that simplify assembly, increase system design options and flexibility, reduce costs through use of decreased IC die area, and allow for more accurate electrical modeling compared to conventional off-chip connection methods.

### SUMMARY

In some embodiments a semiconductor substrate includes a plurality of pads able to support both DC and AC signals with a single connection point to an RF circuit. At least one blocking mechanism on the semiconductor substrate is connected to at least one of the plurality of pads and includes passive components that can prevent unwanted current flow to circuits located externally with respect to the semiconductor substrate.

In some embodiments, at least one of a device and circuit are able to provide both direct current (DC) and radio frequency (RF) functionality and are connectable to the plurality of pads.

In some embodiments, the passive components further comprise capacitors embedded within a device to block DC paths

In some embodiments, the plurality of pads comprise an AC connected pad isolated from at least one DC pad.

In some embodiments, the plurality of pads are connectable to at least one of flip chip, ball grid array (BGA), or land grid array (LGA) designs.

In some embodiments, the plurality of pads are connectable with bond wires.

In some embodiments, the plurality of pads are connectable to a broadband distributed amplifier.

In some embodiments, the plurality of pads are connectable to a filter.

In some embodiments, the plurality of pads are connectable to a wireless communication systems or antennas

In another embodiment, a method of designing a pad layout for a semiconductor substrate includes defining position of a plurality of pads able to support both DC and AC signals with a single connection point to an RF circuit. A position is provided for at least one blocking mechanism on the semiconductor substrate connected to at least one of the plurality of pads and that includes passive components that can prevent unwanted current flow to circuits located externally with respect to the semiconductor substrate

### BRIEF DESCRIPTION OF THE DRAWINGS

Certain aspects of the present technology can be better understood with reference to the following drawings. The relative dimensions in the drawings may be to scale with respect to some embodiments of the present technology. With respect to other embodiments, the drawings may not be to scale. The drawings may also be enlarged arbitrarily. For clarity, reference-number labels for analogous components or features may be omitted when the appropriate reference-number labels for such analogous components or features are clear in the context of the specification and all of the drawings considered together. Furthermore, the same reference numbers may be used to identify analogous components or features in multiple described embodiments.

FIG. 1 illustrates an example PRIOR ART RF chain with multiple semiconductor substrates that includes devices and circuits capable of providing both Direct Current (DC) and Alternating Current (AC) connections.

FIG. 2 illustrates an example PRIOR ART RF chain with multiple semiconductor substrates that includes devices and circuits connected to use DC blocking to prevent unwanted current flow.

FIG. 3A illustrates a novel RF chain with multiple semiconductor substrates that includes devices and circuits capable of providing connection to dual function pads supporting Direct Current (DC) and Alternating Current (AC) connections.

FIG. 3B is an enlarged view of the novel semiconductor substrate of FIG. 3A, showing RF AC and DC circuit pathways and pad connections.

FIG. 4A is view of pad connections able to support RF AC and DC circuit pathways.

FIG. 4B is view of the plurality of pads connectable to at least one of flip chip, ball grid array (BGA), and land grid array (LGA) and able to support RF AC and DC circuit pathways.

### DETAILED DESCRIPTION OF THE DRAWINGS

In the following description, reference is made to the accompanying drawings that form a part thereof, and in which is shown by way of illustrating specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The following detailed description is, therefore, not to be taken in a limiting sense.

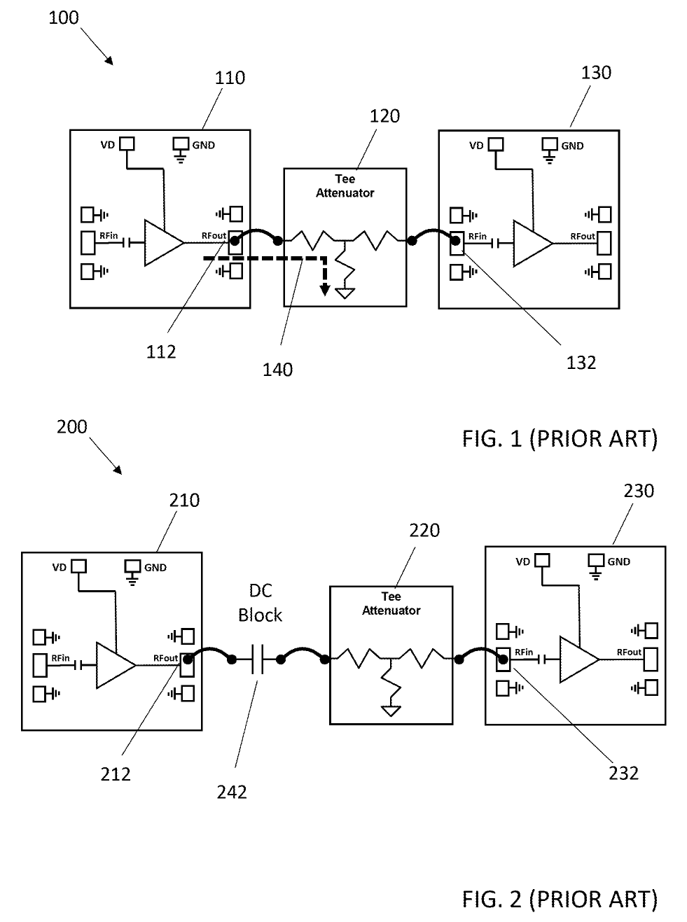

FIG. 1 illustrates an example PRIOR ART RF chain 100 with multiple semiconductor substrates 110 and 130 that includes devices and circuits capable of providing Direct Current (DC) and Alternating Current (AC) connections. The semiconductor substrates 110 and 130 can be connected to each other via a component 120 which can include passive or active components and circuits. In this embodiment, the component 120 supports a tee attenuator. Connection is provided in part using an RF output pad 112 connecting to an RF input pad 132 via connecting pads, wires, or other suitable electrical connectors (not shown) on component 120. Unfortunately, for many RF system designs, unwanted current flow or "sinking" to ground occurs (shown as dotted line 140) when an IC is connected on semiconductor substrate 110 to component 120 and semiconductor substrate 130. Such uncontrolled current flow can degrade IC and circuit performance, cause damage, and compromise both short-term functionality and long-term reliability.

FIG. 2 illustrates an example PRIOR ART RF chain with multiple semiconductor substrates that includes devices and circuits connected to use DC blocking to prevent unwanted current flow such as discussed with respect to FIG. 1. In this embodiment an RF chain 200 with multiple semiconductor substrates 210 and 230 that includes devices and circuits capable of providing Direct Current (DC) and Alternating Current (AC) connections. The semiconductor substrates 210 and 230 can be connected to each other via a component 220 which can include passive or active components and circuits. In this embodiment, the component 220 supports a tee attenuator. Connection is provided in part using an RF output pad 212 connecting to an RF input pad 232 via connecting pads, wires, or other suitable electrical connectors (not shown) on component 220. To prevent unwanted current flow or sinking to ground, a DC block mechanism 242 (optionally including a capacitor) is connected between the semiconductor substrates 210 and the component 220. In an alternative embodiment, the DC block mechanism 242 can be supported on the semiconductor substrate 210 or the component 220. Unfortunately, use of the DC block mechanism 242 can result in impractical limits to the low-frequency bandwidth of RF circuits and can increase costs for the system.

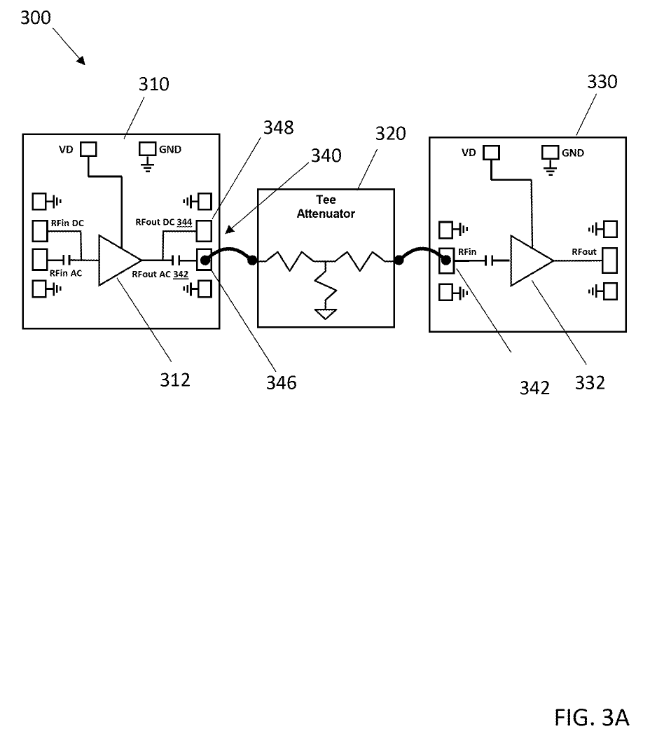

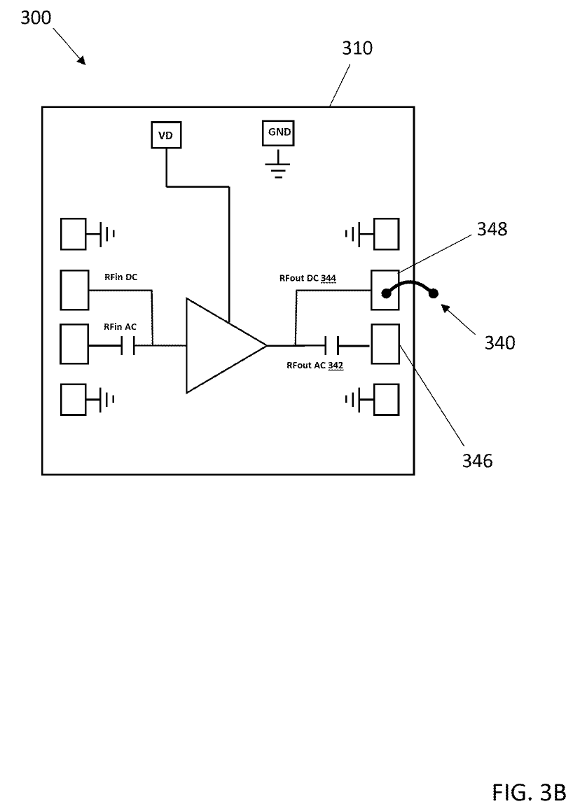

FIG. 3A illustrates a novel RF chain 300A with multiple semiconductor substrates 310A and 330A that includes devices and circuits capable of providing connection to dual function pads 340 supporting Direct Current (DC) and Alternating Current (AC) connections.

As will understood, semiconductor substrates 310 and 330 can include passive or active devices based on silicon (Si) CMOS (Complementary Metal-Oxide-Semiconductor) and III-V GaAs (Gallium Arsenide) substrates or other semiconductor technologies suitable for RF systems. The semiconductor substrates 310 and 330 can be connected to each other via a component 320 which can include passive or active components and circuits. In FIG. 3A, passive components and circuits include but are not limited to a tee attenuator (T-pad) which is a specific type of attenuator circuit which resembles the shape of the letter "T". The tee attenuator consists of one series resistor at the input and two parallel, one of which is grounded while the other goes to output. The tee attenuator is particularly useful for matching impedance in connections between circuits on different substrates, such as shown in FIG. 3A. In other embodiments, the component 320 can include passive filters, capacitors, resistors, attenuators, tee attenuators, or inductors supported on printed circuit boards, redistribution layer (RDL) laminates, ceramic substrates, or low temperature co-fired ceramic (LTCC) substrates.

In some embodiments, the active devices on semiconductor substrates 310 and 330 (or optionally component 320) can include an amplifier 312 connected to the dual output pads 340 via one of a RFout DC connection 344 or an RFout AC connection 344. In the illustrated embodiment, the RFout AC connection 344 is made via a passive component such as capacitor to an AC pad 346. Alternatively, in some cases the RFout DC connection 344 can be made to DC pad 348. Importantly, AC and DC circuits and dual output pads 340 are electrically isolated from each other.

As will be understood, various active and passive electronic components can be supported on semiconductor substrates 310 and 330. The active elements can be transistors and diodes forming a power amplifier, a low noise amplifier, or a switch, for example. The power amplifier can include components such as power detector, a bias control circuit, output impedance matching network, or a current sensing circuit. In some embodiments the RF amplifier can be selected to provides good linearity, high efficiency and low harmonics over a wide frequency range covering from several megahertz (MHZ) to tens of gigahertz (GHZ). The RF amplifier module can be configured to be suitable for use in applications in various wireless data and voice communications standards and protocols, including Global System for Mobile Communications (GSM), General Packet Radio Service (GPRS), Code Division Multiple Access (CDMA), Wideband CDMA, IEEE 802.11, IEEE 802.16 and others.

FIG. 3B is an enlarged view of the novel semiconductor substrate 310 of FIG. 3A, showing in more detail RF AC and DC circuit pathways and pad connections. Advantageously, designing layouts such as discussed with respect to FIGS. 3A and 3B that support electrically isolatable AC and DC output pads 346 and 348 has numerous advantages. For example, compact layout designs can enable dual functionality at a single connection point and offer greater flexibility in RF circuit design. Further, such designs can simplify assembly, reduce costs through use of decreased IC die area, and allow for more accurate electrical modeling compared to conventional off-chip connection methods. Other advantages can include an ability to utilize integrated blocking mechanisms in a compact layout so that DC signals do not interfere with RF performance, enhancing the circuit's reliability and effectiveness.

As another advantage, use of electrically isolatable AC and DC output pads 346 and 348 can benefit design of system-level RF configurations where DC connections may be useful but not always necessary. As an example, dual pads 340 can be used in systems supporting Broadband Distributed Amplifiers (DAs) which often allow for flexible biasing options through the output port or other on-chip bias pads. This flexibility prevents current sourcing or shorts, enhancing amplifier performance and reliability. As another example, filters such as Low Pass Filters (LPF) can optionally be DC coupled to provide signal in some embodiments, but can alternatively be reconfigured using an AC connection to minimize any chance of DC sinking of current into the filter. RF or wireless communication systems are another example of systems that can benefit from use of dual pads 340. The compact and flexible design of circuits using pad 340 connections is well suited for RF chains or line-ups in wireless communication systems, where space and performance are critical, especially in smaller system footprints.

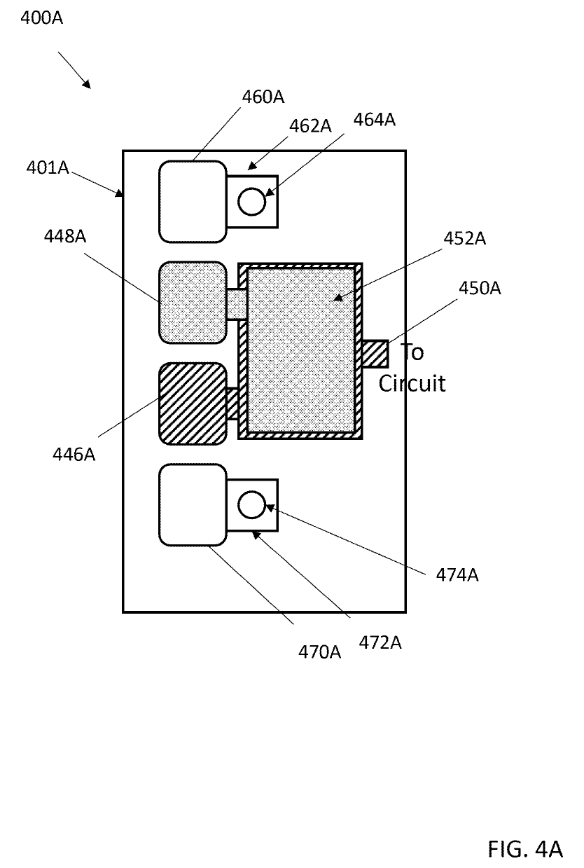

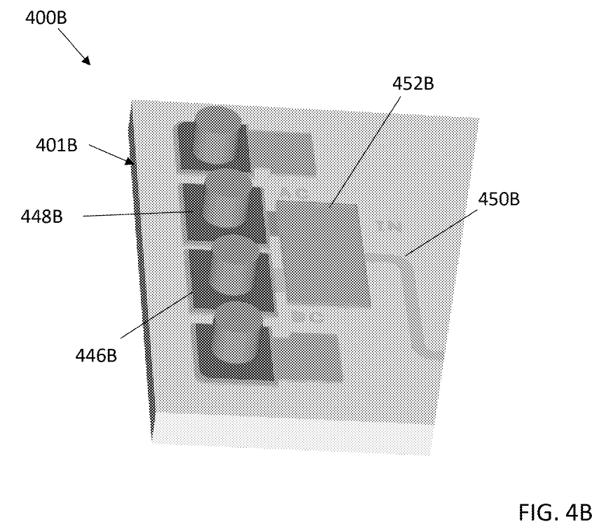

FIG. 4A illustrates representative integrated circuit layout 400A on a substrate 401A, showing a bond pad configuration capable of supporting both Radio Frequency (RF) Alternating Current (AC) and Direct Current (DC) signal pathways. In this embodiment, a DC bond pad 446A is provided, along with an AC bond pad 448A. The AC bond pad 448A is electrically connected to the top plate of an integrated DC blocking capacitor 452A, which is depicted in light gray shading and provides AC coupling to the remainder of the circuit. The DC bond pad 446A, indicated with coarse cross-hatching for visual clarity, is connected to the bottom plate of the DC blocking capacitor 452A. This bottom plate is further connected to a conductive trace 450A, which routes the DC signal into the rest of the integrated circuit. The configuration enables separation of AC and DC signal paths at the bond pad level while minimizing layout area and maintaining electrical isolation where required. Additionally, although not essential to the claimed invention, ground bond pads 460A and 470A are shown, which may be used for RF probing of the structure. These ground pads are connected to via pads 462A and 472A, respectively, which in turn are coupled to RF and DC ground through-vias 464A and 474B extending through the integrated circuit substrate 401A.

FIG. 4B illustrates an alternative view of the integrated circuit layout 400B on a substrate 401B, based on the configuration of layout 400A in FIG. 4A. In this embodiment, a plurality of bond pads is further configured to facilitate external connections via at least one of a flip-chip attachment, a ball grid array (BGA), or a land grid array (LGA). The pillars shown on pads 448B and 446B represent solder balls, copper pillars, or wire bond stud bumps used for physical and electrical interconnection. Similar to the configuration depicted in FIG. 4A, the pads in layout 400B support both RF AC and DC circuit pathways. The integrated structure enables dual-mode (AC/DC) connectivity while accommodating advanced packaging techniques that optimize electrical performance, mechanical reliability, and layout efficiency.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, in alternative embodiments the steps may have another suitable order. Similarly, certain aspects of the present technology disclosed in the context of particular embodiments can be combined or eliminated in other embodiments. Furthermore, while advantages associated with certain embodiments may be disclosed herein in the context of those embodiments, other embodiments may also exhibit such advantages, and not all embodiments need necessarily exhibit such advantages or other advantages disclosed herein to fall within the scope of the present technology. This disclosure and the associated technology can encompass other embodiments not expressly shown or described herein.

Throughout this disclosure, the singular terms "a," "an," and "the" include plural referents unless the context clearly indicates otherwise. Similarly, unless the word "or" is expressly limited to mean only a single item exclusive from the other items in reference to a list of two or more items, then the use of "or" in such a list is to be interpreted as including (a) any single item in the list, (b) all of the items in the list, or (c) any combination of the items in the list. Any reference herein to "the inventors" means at least one inventor of the present technology. As used herein, the terms "generally," "substantially," "about," and similar terms are used as terms of approximation and not as terms of degree, and are intended to account for the inherent variations in measured or calculated values that would be recognized by those of ordinary skill in the art. Additionally, the terms "comprising," "including," "having," and the like as used herein mean including at least the recited feature(s) such that any greater number of the same feature(s) and/or one or more additional types of features are not precluded. This is the case even if a particular number of features is specified unless that specified number is preceded by the word "exactly" or another clear indication that it is intended to be closed ended.

Directional terms, such as "upper," "lower," "front," "back," "vertical," and "horizontal," may be used herein to express and clarify the relationship between various structures. It should be understood that such terms do not denote absolute orientation. Reference herein to "one embodiment," "an embodiment," or similar phrases means that a particular feature, structure, or operation described in connection with such phrases can be included in at least one embodiment of the present technology. Thus, such phrases as used herein are not all referring to the same embodiment. Unless preceded with the word "conventional," reference herein to "counterpart" devices, systems, methods, features, structures, or operations refers to devices, systems, methods, features, structures, or operations in accordance with at least some embodiments of the present technology that are similar to a described device, system, method, feature, structure, or operation in certain respects and different in other respects. Finally, it should be noted that various particular features, structures, and operations of the embodiments described herein may be combined in any suitable manner in additional embodiments in accordance with the present technology.

1. A semiconductor substrate, comprising:
a plurality of pads able to support both DC and AC signals with a single connection point to an RF circuit;
at least one blocking mechanism on the semiconductor substrate connected to at least one of the plurality of pads and comprising passive components that can prevent unwanted current flow to circuits located externally with respect to the semiconductor substrate.

2. The semiconductor substrate of claim 1, further comprising at least one of a device and circuit able to provide both direct current (DC) and radio frequency (RF) functionality and that is connectable to the plurality of pads.

3. The semiconductor substrate of claim 1, wherein the passive components further comprise capacitors embedded within a device to block DC signals

4. The semiconductor substrate of claim 1, wherein the plurality of pads comprise an AC connected pad isolated from at least one DC pad.

5. The semiconductor substrate of claim 1, wherein the plurality of pads are connectable to at least one of flip chip, ball grid array (BGA), and land grid array (LGA).

6. The semiconductor substrate of claim 1, wherein the plurality of pads are connectable with bond wires.

7. The semiconductor substrate of claim 1, wherein the plurality of pads are connectable to a broadband distributed amplifier.

8. The semiconductor substrate of claim 1, wherein the plurality of pads are connectable to a filter.

9. The semiconductor substrate of claim 1, wherein the plurality of pads are connectable to a wireless communication system.

10. A method of designing a pad layout for a semiconductor substrate, comprising:
defining position of a plurality of pads able to support both DC and AC signals with a single connection point to an RF circuit;
providing a position for at least one blocking mechanism on the semiconductor substrate connected to at least one of the plurality of pads and comprising passive components that can prevent unwanted current flow to circuits located externally with respect to the semiconductor substrate.

11. The method of designing a pad layout for a semiconductor substrate of claim 10, further comprising positioning at least one of a device and circuit able to provide both direct current (DC) and radio frequency (RF) functionality and that is connectable to the plurality of pads.

12. The method of designing a pad layout for a semiconductor substrate of claim 10, wherein the passive components further require positioning capacitors embedded within a device to block DC signals

13. The method of designing a pad layout for a semiconductor substrate of claim 10, wherein the plurality of pads comprise an AC connected pad isolated from at least one DC pad.

14. The method of designing a pad layout for a semiconductor substrate of claim 10, wherein the plurality of pads are connectable to at least one of flip chip, ball grid array (BGA), and land grid array (LGA).

15. The method of designing a pad layout for a semiconductor substrate of claim 10, wherein the plurality of pads are connectable with bond wires.

16. The method of designing a pad layout for a semiconductor substrate of claim 10, wherein the plurality of pads are connectable to a broadband distributed amplifier.

17. The method of designing a pad layout for a semiconductor substrate of claim 10, wherein the plurality of pads are connectable to a filter.

18. The method of designing a pad layout for a semiconductor substrate of claim 10, wherein the plurality of pads are connectable to a wireless communication system.
